(19) United States
(12) Patent Application Publication
(10) Pub. No.: US 2024/0068099 A1
(43) Pub. Date: Feb. 29, 2024

(54) SUBSTRATE PROCESSING APPARATUS FOR TEMPERATURE MEASUREMENT OF A MOVING SUBSTRATE AND METHOD OF MEASURING THE TEMPERATURE OF A MOVING SUBSTRATE

(71) Applicant: EVATEC AG, Trübbach (CH)

(72) Inventors: Silvio GEES, Bad Ragaz (CH); Manuel BASELGIA, Chur (CH); Nuno SANTOS, Flums (CH)

(21) Appl. No.: 18/547,584

(22) PCT Filed: Feb. 22, 2022
(86) PCT No.: PCT/EP2022/054422

§ 371 Date: Aug. 23, 2023

(30) Foreign Application Priority Data
Feb. 24, 2021 (CH) 00198/21

(51) Int. Cl. C23C 16/458; C23C 16/52

(52) U.S. Cl. CPC C23C 16/4582; C23C 16/52

(57) ABSTRACT

A substrate processing apparatus is provided. The substrate processing apparatus includes a table rotatable around a first axis, a first holder being arranged in a non-rotatable or rotatable manner on a first side of the table and at least one means for processing a substrate in the first substrate plane and directing towards the first side of the table. Furthermore, the substrate processing apparatus includes a pyrometer being arranged on a second side of the table, the second side of the table facing away from the first side of the table, and an optically operative connection between the pyrometer and the side of a substrate, when positioned on the first holder, facing away from the at least one means for processing a substrate. Furthermore, a method of measuring the temperature of a moving substrate and the use of a substrate processing apparatus for measuring the temperature of a substrate are provided.

### TECHNICAL FIELD OF THE INVENTION

The present invention relates to the technical field of substrate processing apparatuses, in particular of substrate processing apparatuses moving (e.g. rotating) the substrates during processing. It specifically refers to a substrate processing apparatus comprising a pyrometer for measuring the temperature of a moving substrates and to a method of measuring the temperature of a moving substrate. A further aspect of the invention addresses the use of a substrate processing apparatus comprising a pyrometer for measuring the temperature of a moving substrates.

### Definitions

Processing in the sense of this invention includes any chemical, physical or mechanical effect acting on substrates. Furthermore, processing also includes, either alone or in combination with chemical, physical or mechanical effect acting, temperature conditioning. Such conditioning shall be understood to include heating up a substrate to a desired temperature, keeping a substrate at a desired temperature and cooling a substrate to remain at a desired processing temperature, e.g. when the processing itself tends to overheat a substrate.

Substrates in the sense of this invention are components, parts or workpieces to be treated in a processing apparatus. Substrates include—but are not limited to—flat, plate shaped parts having rectangular, square or circular shapes. In a preferred embodiment, this invention addresses essentially planar, circular substrates, such as wafers. The material of such wafers may be glass, semiconductor, ceramic or any other substance able to withstand the processing temperatures described.

A vacuum processing or vacuum treatment system/apparatus/chamber comprises at least an enclosure for substrates to be treated under pressures lower than ambient atmospheric pressure plus means for processing said substrates.

A chuck or clamp is a substrate holder or support, adapted to fasten a substrate during processing. This clamping may be achieved, inter alia, by electrostatic forces (electrostatic chuck ESC), mechanical means, vacuum or a combination of aforesaid means. Chucks may exhibit additional facilities like temperature control components (cooling, heating) and sensors (substrate orientation, temperature, warping, etc.)

CVD or Chemical Vapour Deposition is a chemical process allowing for the deposition of layers on heated substrates. One or more volatile precursor material(s) are being fed to a process system where they react and/or decompose on the substrate surface to produce the desired deposit. Variants of CVD include: Low-pressure CVD (LPCVD)—CVD processes at sub-atmospheric pressures. Ultrahigh vacuum CVD (UHVCVD) are CVD processes typically below 10⁻⁶ Pa/10⁻⁷ Pa. Plasma methods include Microwave plasma-assisted CVD (MPCVD), Plasma-Enhanced CVD (PECVD). These CVD processes utilize plasma to enhance chemical reaction rates of the precursors.

Physical vapour deposition (PVD) is a general term used to describe any of a variety of methods to deposit thin films by the condensation of a vaporized form of a material onto a surface of a substrate (e.g. onto semiconductor wafers). The coating method involves purely physical processes such as high temperature vacuum evaporation or plasma sputter bombardment in contrast to CVD. Variants of PVD include Cathodic Arc Deposition, Electron beam physical vapour deposition, Evaporative deposition, Sputter deposition (i.e. a glow plasma discharge usually confined in a magnetic tunnel located on a surface of a target material).

The terms layer, coating, deposit and film are interchangeably used in this disclosure for a film deposited in vacuum processing equipment, be it CVD, LPCVD, plasma enhanced CVD (PECVD) or PVD (physical vapour deposition).

### BACKGROUND OF THE INVENTION

Substrate processing apparatuses and methods of processing substrates or manufacturing processed workpieces in a substrate processing apparatus are wildly known. It is also known that there is a plurality of parameters, such as pressure, temperature, processing time and alike, influencing the quality of the processed product, i.e. the processed substrate or workpiece. However, measuring and controlling such parameters in real life, and in particular in real time, can be rather challenging. Consequently, there is a constant need of controlling such parameters in a more reliable and precise way in order to enhance the quality of the processed product, e.g. by providing improved substrate processing apparatuses and/or improved methods of measuring such parameters. In particular for apparatuses where the substrate is coated and heated from the same side, it can be very difficult to detect the actual conditions of the substrate during processing. In the state of the art most often resistance temperature sensors, such as PT100 sensors or thermocouples, are mounted on a substrate holder or carrier for temperature measurements. However, thermocouples and resistance temperature sensors require complex electrical feedthroughs, this being in particular challenging when the temperature of a moving substrate, e.g. a substrate located on a rotatable table and/or a rotatable substrate support is to be measured. Alternatively, pyrometers (i.e. thermal radiation sensors) can be used, but they are highly sensitive towards undesired background radiation emitted by the heater and the CVD or PVD source, thereby falsifying the temperature measurement result. Furthermore, the emissivity of the growing coating on the substrate changes over time, also having a negative impact on the measurement result.

The object of the present invention is to provide a substrate processing apparatus for an improved temperature measurement of a moving substrate. Furthermore, the object of the invention can be phrased as provision of an improved method of measuring the temperature of a moving substrate.

The object of the invention is achieved by a substrate processing apparatus according to claim 1.

The substrate processing apparatus comprises a table that is rotatable around a first axis. The table comprises at least one first passage which is transparent to radiation. On a first side of the table, at least one first holder is arranged in a non-rotatable (or in other words: fixed, non-movable) manner. The at least one first holder is designed to support a substrate and defines a first substrate plane. The at least one first holder provides at least one second passage which is transparent to radiation. Furthermore, the substrate processing apparatus comprises at least one means for processing a substrate that is located in the first substrate plane. The at least one means for processing a substrate is arranged facing the first substrate plane and the first side of the table. Moreover, the substrate processing apparatus comprises a pyrometer that is arranged on a second side of the table, which second side of the table faces away from the first side of the table. The at least one first passage and the at least one second passage form an optically operative connection between the pyrometer and the side of a substrate (when positioned in the first substrate plane) that faces away from the at least one means for processing a substrate.

The substrate processing apparatus according to the invention allows to measure the temperature of a substrate “from below”, i.e., from the not-to-be-processed-side, and thus not (only) from the “top”, i.e., from the to-be-processed-side. In the state of the art, the measurement is in general made from the top. One reason is that the substrate is normally well structurally shielded from below and measuring from the top is thus less complicated. However, one of the advantages of measuring from below is that the surface of the substrate from the side, where the temperature is measured, is not changed or altered due to the processing result and thus results in a more precise temperature measurement. This is in particular the case for glass or silicon substrates. Moreover, less or even none of the heat radiation of the means for processing a substrate will reach the pyrometer and falsify the measurement result. For instance, the optically operative connection, which can also be described as optical path, can be realized as a physical passage (e.g., through hole or window transparent to radiation) but also by means of mirrors leading the radiation from the substrate to the pyrometer without penetrating any physical barrier.

Although the previously described substrate processing apparatus comprises a rotatable table configured to set one or more substrates positioned thereupon in rotation, the invention is of course also applicable to a table or conveyer belt moving the one or more substrates in a general and not specifically rotatable manner, such as a linear movement.

In one embodiment of the substrate processing apparatus according to the invention, which may be combined with any of the embodiments still to be addressed unless in contradiction, the substrate processing apparatus further comprises at least one second holder for supporting a substrate and defining a second substrate plane. The second holder is arranged in a rotatable manner around a second axis on the first side of the table. The second axis is different from the first axis. They are not congruent. In particular no optically operative connection is provided between the pyrometer and the side of a substrate (when positioned in the second substrate plane) that faces away from the at least one means for processing a substrate.

In this embodiment, the temperature measurement is performed only for a substrate that gets rotated by the table but not by the holder. Most often this monitored substrate is a dummy or test substrate that is used for further tests and/or quality measurements but not for sale. The other substrate (or substrates, if there are more than just one second holder) is additionally rotated around a second axis to improve the result of the processing. One of the advantages of this embodiment is the more cost-efficient realization.

Although the previously described substrate processing apparatus comprises a rotatable table configured to set one or more substrates positioned thereupon in a first rotation, the invention is of course also applicable to a table or conveyer belt configured to move the one or more substrates in a general and not specifically rotatable manner, such as a linear movement. The second holder can nonetheless be arranged in a rotatable manner on the first side of the table or conveyer belt moving in a linear manner, for instance.

The object of the invention is further achieved by a substrate processing apparatus according to claim 3.

The substrate processing apparatus comprises a table that is rotatable around a first axis. The table comprises at least one first passage that is transparent to radiation. Furthermore, the substrate processing apparatus comprises at least one first holder for supporting a substrate and defining a first substrate plane. The first holder is arranged in a rotatable manner around a second axis on a first side of the table and provides at least a second passage that is transparent to radiation. The second axis is in particular different from the first axis, i.e., they are not congruent. Moreover, the substrate processing apparatus comprises at least one means for processing a substrate in the first substrate plane. The at least one means for processing a substrate is arranged facing the first substrate plane and the first side of the table. The substrate processing apparatus also comprises a pyrometer that is arranged on a second side of the table. The second side of the table faces away from the first side of the table. The at least one first passage and the at least one second passage form an optically operative connection between the pyrometer and the side of a substrate (when positioned in the first substrate plane) that faces away from the at least one means for processing a substrate.

In this embodiment, the temperature of a substrate can be monitored that is rotated by the table and the holder on the table. This means that the measurement is not performed on a dummy or test substrate but on a regular one. Although the set-up of the substrate processing apparatus is more complicated this way, better monitoring results can be achieved when the substrate that is monitored is treated exactly the same way than the remaining processed substrates. Moreover, the production is more efficient since no dummy or test substrate accrues.

Although the previously described substrate processing apparatus comprises a rotatable table configured to set one or more substrates positioned thereupon in a first rotation, the invention is of course also applicable to a table or conveyer belt configured to move the one or more substrates in a general and not specifically rotatable manner, such as a linear movement. The first holder can nonetheless be arranged in a rotatable manner on the first side of the table or conveyer belt moving in a linear manner, for instance.

In one embodiment of the previous substrate processing apparatus according to the invention, which may be combined with any of the embodiments still to be addressed unless in contradiction, the substrate processing apparatus comprises at least one second holder for supporting a substrate and defining a second substrate plane. The second holder is arranged either in a rotatable manner around a third axis on the first side of the table or in a non-rotatable manner. The third axis is different from the first axis and the second axis. The three are not congruent. In particular no optically operative connection is provided between the pyrometer and the side of a substrate (when positioned in the second substrate plane) that faces away from the at least one means for processing a substrate.

This embodiment is of course also applicable to a table or conveyer belt configured to move the one or more substrates in a general and not specifically rotatable manner, such as a linear movement. The third holder can nonetheless be arranged in a rotatable or non-rotatable manner on the first side of the table or conveyer belt moving in a linear manner, for instance.

In one embodiment of one of the substrate processing apparatuses according to the invention, which may be combined with any of the preaddressed embodiments and any of the embodiments still to be addressed unless in contradiction, the table, the at least one means for processing a substrate in the first substrate plane and the at least one first holder are arranged within a vacuum enclosure. Alternatively, the table, the at least one means for processing a substrate in the first substrate plane, the at least one first holder and the at least one second holder are arranged within a vacuum enclosure. However, the pyrometer is arranged outside of said vacuum enclosure and the vacuum enclosure comprises a third passage that is transparent to radiation. The third passage forms together with the at least one first passage and the at least one second passage the optically operative connection between the pyrometer and the side of a substrate (when positioned in the first substrate plane) that faces away from the at least one means for processing a substrate.

The pyrometer can in general be arranged within or outside of the vacuum enclosure. However, it is beneficial to place as little technique in the vacuum enclosure as possible since all items in the vacuum are exposed to a wide pressure range that can cause stress. Furthermore, the smaller the vacuum chamber, the fewer time and energy is needed for applying the vacuum.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, at least one of the first passage, the second passage and the third passage comprises silicon (Si) and/or germanium (Ge). In particular it is at least the third passage that comprises silicon (Si) and/or germanium (Ge).

These materials are beneficial as they are transparent to a radiation range well suitable for executing the temperature measurement. Moreover, these materials can well handle a wide pressure range without losing their sealing characteristic.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the substrate processing apparatus further comprises an additional pyrometer that is also in optically operative connection with the side of a substrate (when positioned in the first substrate plane) that faces away from the at least one means for processing a substrate. The optically operative connection is provided by means of the at least one first passage and the at least one second passage or by means of the at least one first passage, the at least one second passage and the at least one third passage. Alternatively, the optically operative connection is provided by means of further passages that are different from the at least one first passage and the at least one second passage or the at least one first passage, the at least one second passage and the at least one third passage, respectively. The pyrometer and the additional pyrometer are configured to receive radiation from the side of a substrate (when positioned in the first substrate plane) that faces away from the at least one means for processing a substrate. The pyrometer and the additional pyrometer are in particular configured to receive radiation in an alternating manner.

In this embodiment it is not only one pyrometer that is measuring radiation emitted from the substrate through the one or more optically operational connection(s). When using two pyrometers or more, a more continuous temperature monitoring can be achieved. Each pyrometer has a certain response time and when implementing the pyrometers in an alternating or sequential manner, more measurement results can be gained over the same time period. This is in particular interesting when the table is turning rather fast, let's say with about 120 rpm instead of only 40 rpm. In consequence, only one instead of three measurement values will become available per 360° rotation. Each additional pyrometer provides a further measurement value and thus provides for a more stable overall result by calculating the average value. When performing the temperature measurement by the means of the two or more pyrometers at the same time, a temperature profile of the substrate can be gained. In particular when the pyrometers are not arranged directly next to each other but at a certain distance and on different radii, for instance one pyrometer is located centralized, the additional pyrometer is located decentralized at a distance being, e.g., half or three quarter or 100% of the radius of the substrate to be treated, a proper temperature profile can be gained. In another example, the pyrometers are arranged at a maximum distance to still use the identical optically operational connection.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the substrate processing apparatus further comprises an additional pyrometer that is in optically operative connection with the side of a substrate (when positioned in the first substrate plane) that faces to the at least one means for processing a substrate. The optically operative connection is provided in particular by means of a fourth passage that is different from the at least one first passage, the at least one second passage, and the at least one third passage. The additional pyrometer is configured to receive radiation from the side of a substrate (when positioned in the substrate plane) that faces to the at least one means for processing a substrate.

In this embodiment, the temperature of the substrate is measured from both its side, namely the side facing towards the means for processing a substrate and the side facing away from the means for processing a substrate. A more precises temperature profile can be gained this way. It is possible to measure the temperature of the same substrate by means of the two or more pyrometers, but it is also possible to measure the temperature of different substrates this way, i.e., when the two or more pyrometers are arranged at different segments of the table and the measurement is performed more or less at the same time. Furthermore, it is possible to measure the temperature of the same substrate but at different positions of the rotation, i.e., when the two or more pyrometers are arranged at different segments of the table and the measurement is performed at different times or in other words time-delayed. In an example, the additional pyrometer shows a larger integration time than the pyrometer, such that the pyrometer is actually measuring the temperature of the substrate, the additional pyrometer, however, is measuring an average value over the table and substrate(s). In another example, the additional pyrometer is positioned such that there is no optically operative connection to a substrate, irrespective of the position of the table in respect to the first axis. However, it is provided an optically operative connection between the additional pyrometer and the table to determine the temperature of the table. The integration time of the additional pyrometer is not important in this example as there is only an optically operative connection to the table. In a further example, the additional pyrometer is positioned such that, depending on the optically operative connection, an optically operative connection to the table or to a substrate is established. Since the integration time of the additional pyrometer is short enough, not an average temperature value over the table and substrate(s) is determined but the actual temperature of the table. The additional pyrometer can either be triggered to solely generate measurement results when the additional pyrometer is in optically operative connection to the table by a synchronization means, for instance, or the additional pyrometer itself is configured to only forward non-maximum values, e.g., minimum values, or a controlling device in operational connection with the additional pyrometer is implemented and configured to identify and forward non-maximum values, e.g., minimum values, only.

This embodiment is of course also applicable to a table or conveyer belt configured to move the one or more substrates in a general and not specifically rotatable manner, such as a linear movement.

In one embodiment of the previous substrate processing apparatus according to the invention, which may be combined with any of the preaddressed embodiments and any of the embodiments still to be addressed unless in contradiction, the pyrometer and the additional pyrometer are arranged such that the optically operative connection with the side of a substrate (when positioned in the first substrate plane) that faces away from the at least one means for processing a substrate, and the optically operative connection with the side of a substrate (when positioned in the first substrate plane) that faces to the at least one means for processing a substrate, are congruent or distinct.

In case they are congruent, the same spot of the same substrate can be monitored from top and below (in case the measurement is performed at the same time). When the measurements are performed time-delayed, a temperature profile can be gained. In case they are distinct, different spots and thus a temperature profile of the same substrate can be gained (in case the measurement is performed at the same time). When the measurements are performed time-delayed, and in particular synchronized with the rotation of the substrate, the same spot of the same substrate can be monitored from top and below.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the pyrometer and/or the additional pyrometer are configured to receive radiation of a wavelength of 5 to 14 μm, in particular of 5 to 8 μm or 8 to 14 μm, further in particular of 7.9 μm or 12 μm.

These are the wavelengths that in particular penetrate through silicon (Si) and germanium (Ge), therefore allowing a reliable measurement result for optical paths comprising at least one of these materials. In an example, the pyrometer and the additional pyrometer are configured identical, in particular configured to receive radiation of the same wavelength or wavelength range. This is, e.g., beneficial when more measurement values are preferred to gain an average value, a temperature profile or alike. In another example, the pyrometer and the additional pyrometer are configured differently, in particular configured to receive radiation of different wavelengths or different wavelength ranges. This way, the pyrometers can be optimized for substrates of different materials. Depending on the type of substrate, the temperature measurement is performed with one or the other pyrometer. Alternatively, only the measurement values provided by the pyrometer best suitable für the substrate are processed. “Configured” in the context of the optimization for the temperature measurement of different substrates is not limited to the reception of radiation of specific wavelengths. For instance, the integration time, the area designed to receive radiation, the depth of the light receiver, the (height-)position in relation to the substrate, the presence or material of a sleeve, . . . and even more characteristics of the pyrometer can be configured to achieve an optimized measurement depending on the material of the substrate.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the embodiments still to be addressed unless in contradiction, the integration time of the pyrometer and/or of the additional pyrometer is 15 ms or less, in particular 10 ms or less, and further in particular 5 ms or less.

Such short integration times are in particular helpful when desiring a high frequent temperature monitoring, but also when having high rotation speeds.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the optically operative connection between the side of a substrate (when positioned in the first substrate plane) that faces away from the at least one means for processing a substrate, and the pyrometer and/or the additional pyrometer is designed such that the pyrometer and/or the additional pyrometer receive radiation emitted centralized from the substrate and/or decentralized from the substrate.

In particular for larger substrates, it can be interesting to have a temperature profile from the center of the substrate to its edges such that one pyrometer measures centralized, and the additional pyrometer decentralized. For smaller substrates, a centralized measurement gives the best overview of the temperature of the substate in general. But there are also processing applications possible where a decentralized measurement is preferred.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the substrate processing apparatus further comprises an optical monitor and/or at least one lens being part of the optically operative connection between the pyrometer and the substrate and/or at least one lens being part of the optically operative connection between the additional pyrometer and the substrate.

The optical monitor is, in addition to the at least one pyrometer, a second means for quality control and can supervise the substrate processing procedure. Therefore, the optical monitor is in particular arranged on the side of the table where the means for processing are arranged too. A lens as part of the optically operative connection helps to bundle or scatter radiation from the substrate to optimize the beam received by the pyrometer and thus to improve the whole temperature measurement.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the substrate processing apparatus further comprises a means for synchronization.

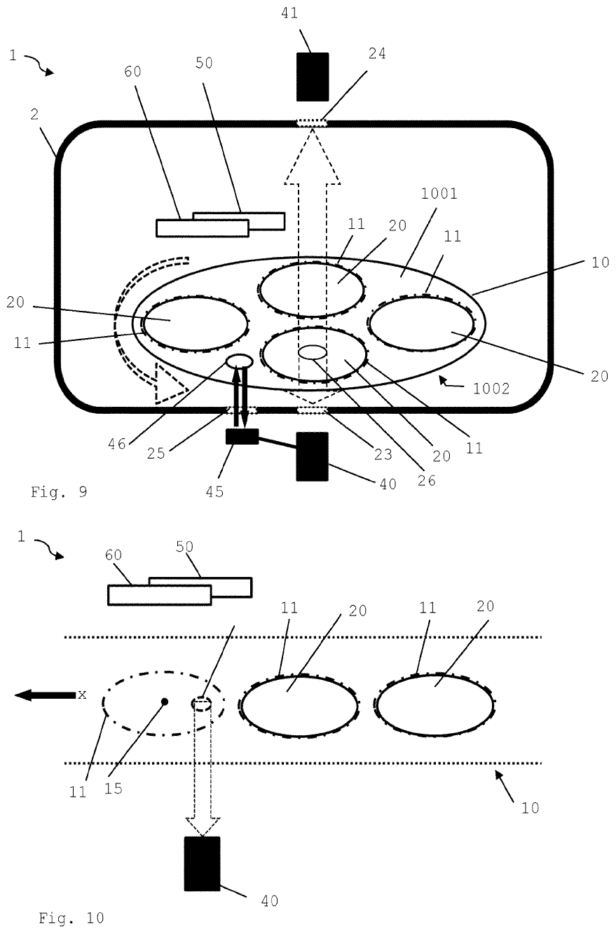

Such a means for synchronization is constructed to synchronize the emission measurement performed by the pyrometer and the rotation of the substrate(s), namely the movement, such as the rotation, of the holder(s) for supporting the substrate and/or the table supporting the holder(s). Alternatively, the means for synchronization is constructed to synchronize the emission measurement performed by the additional pyrometer or the pyrometer and the additional pyrometer and the rotation of the table around the axis and/or the rotation of the first holder around the second axis, such that the pyrometer and/or the additional pyrometer measure emission only when it/they is/are in optically operative connection to the substrate, when positioned in the first substrate plane. The pyrometer(s) performed the measurement thus not constantly but selectively. Examples of means for synchronization are further explained in connection with FIG. 9 and understood to be independently combinable with any of the preaddressed embodiments of the invention and any of the embodiments of the invention still to be addressed unless in contradiction.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the substrate processing apparatus comprises at least one means for synchronization to synchronize the forwarding of the emission measurement performed by the pyrometer and/or by the additional pyrometer and the rotation of the table around the axis and/or the rotation of the first holder around the second axis, such that only emission measurements are forwarded that are performed when the pyrometer and/or the additional pyrometer are in optically operative connection to the substrate, when positioned in the first substrate plane. The synchronization mechanism of the means for synchronization is in particular based on the rise of the signal, namely the temperature measured by the (additional) pyrometer, which rise is caused by the establishment of the optically operative connection between the pyrometer and/or the additional pyrometer and the substrate, when positioned in the first substrate plane. The synchronization mechanism of the means for synchronization is further in particular based on the fall of the signal caused by the termination of the optically operative connection between the pyrometer and/or the additional pyrometer and the substrate, when positioned in the first substrate plane.

In an example, the pyrometer measures constantly, however, on a user interface only a single value is shown. Since the means for synchronization is programmed such that it identifies and forwards the maximum value—or the maximum values in case the pyrometer is brought into optically operative connection with more than one substrate on a 360° rotation of the table. Alternatively, the means for synchronization does not identify the maximum value(s) by analyzing the measurement values of the past 360° rotation of the table, but right away. To achieve a prompt identification of the maximum, the means for synchronization initiates the forwarding of one or more measurement values whenever a predefined positive gradient of the curve of measurement values is reached and stops forwarding the one or more measurement values whenever a predefined negative gradient of the curve of measurement values is reached. Depending on the rotation speed of the table (and the holder, where applicable) and the dimension of the passages providing for the optically operative connection between the pyrometer and the substrate, between 1 to 3 or even 5 measurement values are detected per substrate and 360° rotation of the table. In an example, the table rotates with 12 to 120 rpm, in particular with approximately 40 rpm. At 120 rpm only 1 measurement value is available per substrate and full rotation of the table, for instance. At 40 rpm about 3 measurement values are available per substrate and full rotation of the table, for instance. The means for synchronization adapts automatically to the rotation speed of the table as can be derived from the exemplarily above-described modes of operation. This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the pyrometer and/or the additional pyrometer are configured to measure a temperature permanently during a 360° rotation of the table around the first axis. Furthermore, the pyrometer and/or the additional pyrometer are configured to only forward maximum values, in particular 1 to 3 maximum values per one 360° rotation. Alternatively, the substrate processing apparatus further comprises a controlling device in operational connection with the pyrometer and/or the additional pyrometer and configured to identify and forward maximum values only, in particular 1 to 3 maximum values per one 360° rotation.

In this embodiment, the pyrometer(s) does/do only provide the actual temperature values of the substrate(s) by forwarding only these values to a user interface or processor, although the measurement is performed continuously. The selection of measurement values is therefore performed within the pyrometer. Alternatively, the pyrometer and/or the additional pyrometer is in operational connection with a controlling device, which controlling device is configured to identify and forward maximum values only.

This embodiment is of course also applicable to a table or conveyer belt configured to move the one or more substrates in a general and not specifically rotatable manner, such as a linear movement.

In one embodiment of one of the substrate processing apparatuses according to the invention, which may be combined with any of the preaddressed embodiments and any of the embodiments still to be addressed unless in contradiction, the table is configured to have a speed between 12 to 120 rpm, in particular approximately 40 rpm.

A further aspect of the invention addresses the use of one of the substrate processing apparatuses according to the invention for measuring the temperature of a substrate, in particular for measuring the temperature of a moving substrate and further in particular of a rotating substrate. The rotating substrate rotates preferably around a first rotation axis and/or a second rotation axis.

An even further aspect of the invention addresses a method of measuring the temperature of a moving substrate. The method comprises rotating a substrate around a first axis on a table of a substrate processing apparatus or moving a substrate along a first direction on a table or conveyer belt of a substrate processing apparatus and providing at least one means for processing the substrate from a first side. Furthermore, the method comprises receiving radiation emitted from a second side of the substrate by means of a pyrometer through an optically operative connection between the pyrometer and the substrate. The second side of the substrate is opposite to said first side.

The method thus allows the treatment of a substrate from one side and the measurement of its temperature from the other, namely the opposite side. This leads to a more precise measurement result since less scattered radiation originating from the means for processing the substrate is detected.

In one embodiment of the method according to the invention, which may be combined with any of the embodiments still to be addressed unless in contradiction, the method further comprises rotating the substrate around a second axis on a holder supporting the substrate. The holder is arranged on the table.

For a more even substrate processing result, it can be advisable to rotate the substrate to be processed around two different axes. For reasons of quality control, it is helpful to have a method at hand that allows for an precise temperature measurement even for substrates rotating around two different axes.

In one embodiment of the method according to the invention, which may be combined with any of the preaddressed embodiments and any of the embodiments still to be addressed unless in contradiction, the method further comprises receiving radiation emitted from the second side of the substrate by means of an additional pyrometer through the optically operative connection between the pyrometer and the substrate. The second side is opposite to said first side. Alternatively, or in addition, the method further comprises receiving radiation emitted from the second side of the substrate by means of an additional pyrometer through an additional optically operative connection between the additional pyrometer and the substrate. The second side is opposite to said first side. Alternatively, or in addition, the method further comprises receiving radiation emitted from the first side of the substrate by means of an additional pyrometer through an additional optically operative connection between the additional pyrometer and the substrate.

When using two pyrometers or more, a more continuous temperature monitoring can be achieved. Further explanation is given in connection with the embodiment of the substrate processing apparatus further comprising an additional pyrometer.

In one embodiment of the method according to the invention, which may be combined with any of the preaddressed embodiments and any of the embodiments still to be addressed unless in contradiction, the method further comprises synchronizing the movement, such as the rotation, of the substrate around the first axis and/or the second axis with the reception of radiation through the optically operative connection between the pyrometer and the substrate. Alternatively, or in addition, the method further comprises synchronizing the movement, such as the rotation, of the substrate around the first axis and/or the second axis with the reception of radiation through the optically additional operative connection between the additional pyrometer and the substrate.

The better the synchronization is, the higher is the amount of emitted light to be received by the pyrometer, and the more precise becomes the measurement result. Furthermore, the synchronization can be optimized in a way to skip the response time of the pyrometer and exploit its measurement time frame best.

In one embodiment of the method according to the invention, which may be combined with any of the preaddressed embodiments and any of the embodiments still to be addressed unless in contradiction, the reception of radiation emitted from a second side of the substrate by means of a pyrometer through an optically operative connection between the pyrometer and the substrate, the second side being opposite to said first side, and the reception of radiation emitted from the first side of the substrate by means of an additional pyrometer through an additional optically operative connection between the additional pyrometer and the substrate are performed at the same time, temporally shifted, congruent and/or distinct.

When using two pyrometers or more to, e.g., measure the temperature of a substrate from both sides, a more exact temperature monitoring can be achieved. Further explanation is given in connection with the embodiment of the substrate processing apparatus further comprising an additional pyrometer that is in optically operative connection with the side of a substrate (when positioned in the first substrate plane) that faces to the at least one means for processing a substrate.

In one embodiment of the method according to the invention, which may be combined with any of the preaddressed embodiments and any of the embodiments still to be addressed unless in contradiction, the pyrometer and/or the additional pyrometer receives radiation only when the pyrometer and/or the additional pyrometer is in optically operative connection with the substrate. Alternatively, the pyrometer and/or the additional pyrometer processes received radiation to a temperature value only when the pyrometer and/or the additional pyrometer is in optically operative connection with the substrate.

In an example, the (additional) pyrometer can physically be covered whenever the table is in a position that no optically operative connection between the (additional) pyrometer and the substrate is established. In consequence, the (additional) pyrometer cannot receive any radiation.

Alternatively, the (additional) pyrometer can be controlled electronically to not receive or process any received radiation whenever the table is in a position that no optically operative connection between the (additional) pyrometer and the substrate is established. Thus, only temperature values that show the actual temperature of the substrate and not of anything else are provided.

In one embodiment of the method according to the invention, which may be combined with any of the preaddressed embodiments and any of the embodiments still to be addressed unless in contradiction, the method further comprises the reception of radiation emitted from the table by means of the pyrometer and/or the additional pyrometer. According to one aspect, only emission measurements performed when the pyrometer and/or the additional pyrometer is in optically operative connection with the substrate are provided. The provision is, for instance, performed by the (additional) pyrometer itself, a means of synchronization or a controlling device. According to another aspect, only emission measurements performed when the pyrometer and/or the additional pyrometer is in optically operative connection with the table and not with the substrate are provided. In an even further aspect, emission measurements performed when the pyrometer and/or the additional pyrometer is in optically operative connection with the table and with the substrate are provided.

Depending on the aspect of this embodiment, it is possible to gain temperature information for the substrate only, for the table only or for the substrate and the table.

The invention shall now be further exemplified with the help of figures. The figures schematically show:

FIG. 1 a schematic illustration of a substrate processing apparatus according to the invention;

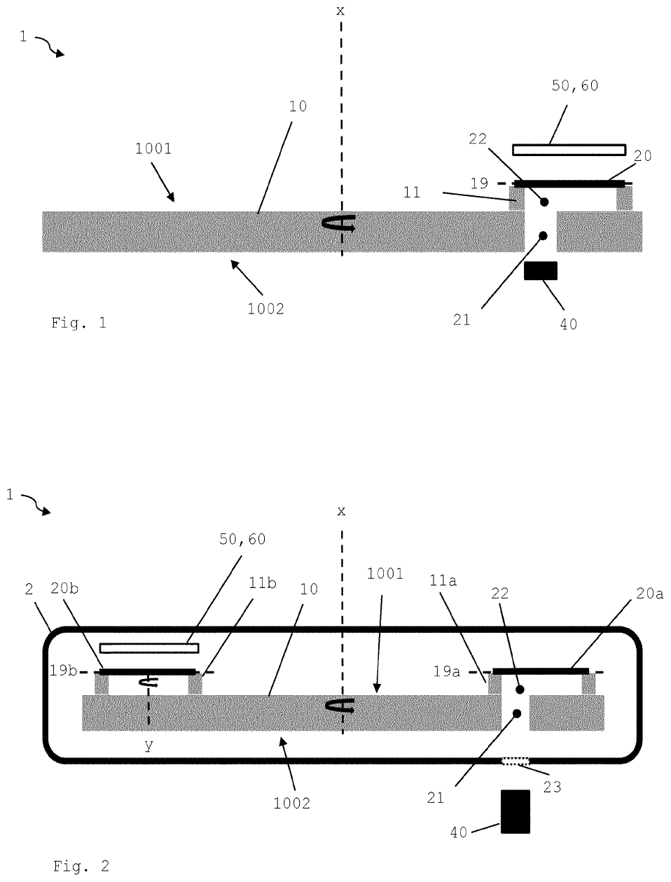

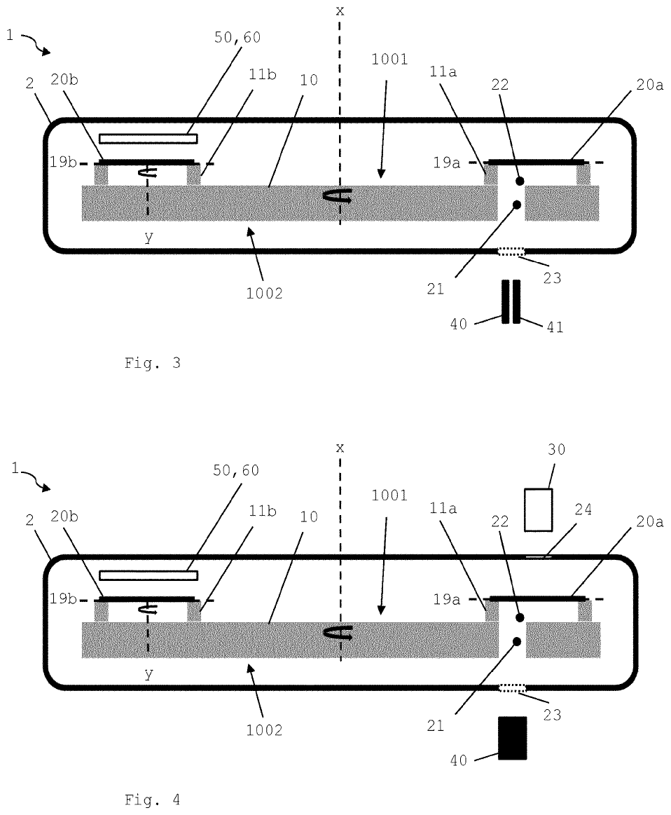

FIG. 2 a schematic illustration of an embodiment of a substrate processing apparatus according to the invention;

FIG. 3 a schematic illustration of a further embodiment of a substrate processing apparatus according to the invention;

FIG. 4 a schematic illustration of a further embodiment of a substrate processing apparatus according to the invention;

FIG. 5 a schematic illustration of a further embodiment of a substrate processing apparatus according to the invention;

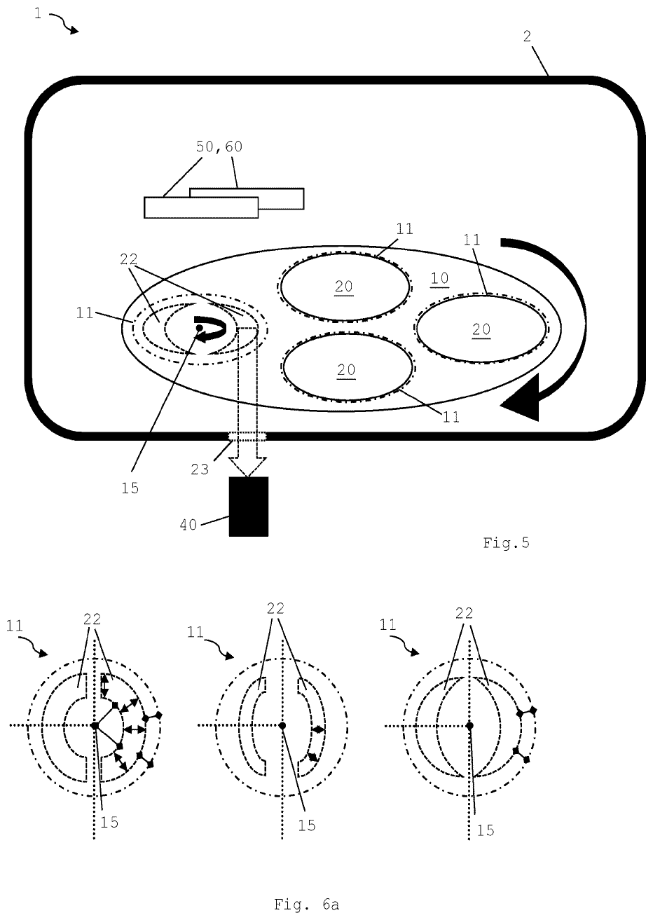

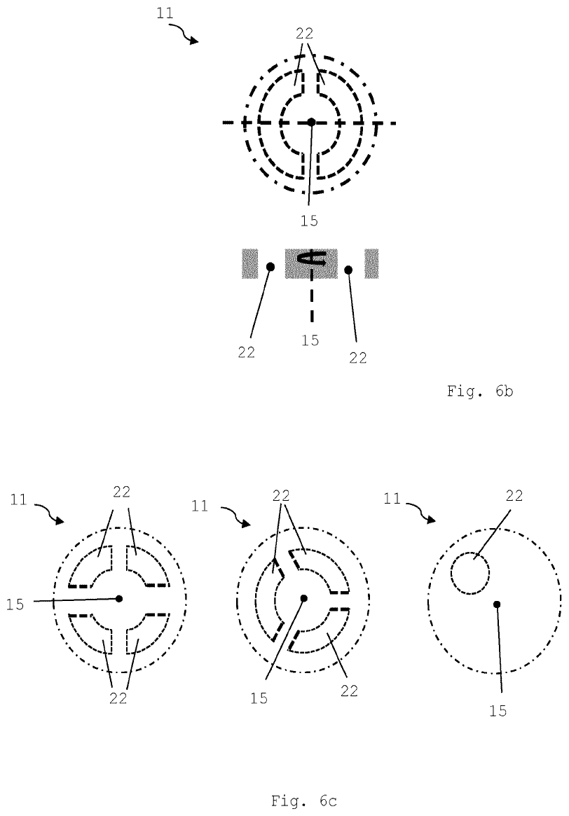

FIG. 6a a schematic illustration of various embodiments of a substrate holder to be used in a substrate processing apparatus according to the invention;

FIG. 6b a schematic illustration in top view and cross section of an embodiment of a substrate holder to be used in a substrate processing apparatus according to the invention;

FIG. 6c a further schematic illustration of various embodiments of a substrate holder to be used in a substrate processing apparatus according to the invention;

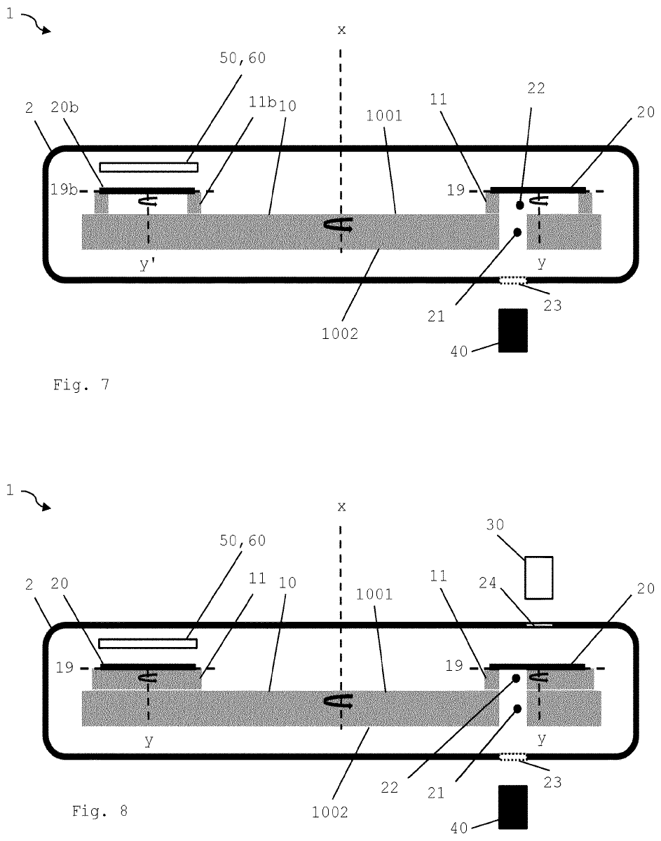

FIG. 7 a schematic illustration of a further embodiment of a substrate processing apparatus according to the invention;

FIG. 8 a schematic illustration of a further embodiment of a substrate processing apparatus according to the invention;

FIG. 9 a schematic illustration of a further embodiment of a substrate processing apparatus according to the invention; and

FIG. 10 a schematic illustration of a further embodiment of a substrate processing apparatus according to the invention.

FIG. 1 shows a sectional view of a substrate processing apparatus 1 comprising a table 10 rotatable around a first rotation axis x. In case the table 10 has an essentially cylindric shape and is thus rotationally symmetric, the first rotation axis x may be identical in position to the rotational symmetry axis of the table 10. Furthermore, the substrate processing apparatus 1 comprises a holder 11 for supporting a substrate 20. The holder 11 is arranged in a static, i.e. non-rotatable, manner on one side of the table being specified as first side of the table 1001. Moreover, the holder defines a substrate plane 19. For instance, the holder 11 is designed as continuous or interrupted ring-shaped chuck supporting the circumference of the substrate 20. In order to process the substrate 20, the substrate processing apparatus 1 comprises at least one means for processing a substrate, such as a heater 50 and/or a source 60 (e.g. CVD source or PVD source such as a target or sputter source). The heater 50 and the source 60 are both (if both are present, otherwise this statement applies to the one of them being present) arranged such that they can process a substrate 20 in the substrate plane 19 from the side of the substrate 20 pointing away from the table 10, in particular pointing away from the first side of the table 1001, when the substrate 20 in the substrate plane 19 driven by the rotatable table 10 passes by the heater 50 and/or source 60. The heater 50 and/or the source 60 are arranged in a top region of the substrate processing apparatus 1, for instance. Please note that the substrate plane 19 is introduced to be able to describe the set-up of the substrate processing apparatus 1 without requiring the actual presence of a substrate 20. The substrate plane 19 symbolizes or represents a substrate 20 positioned on the holder 11. Although a substrate 20 is not necessarily a flat and therefore almost two-dimensional geometrical body, the simplification as a “plane” does not have any impact on the functionality of the substrate processing apparatus 1. In other words, nothing changes when a substrate 20 on the holder 11 is not flush with the substrate plane 19 but protrudes from the substrate plane 19 either in direction of the means for processing 50, 60 or in direction of the table 10 or in both directions. To monitor the substrate processing, the temperature of the substrate 20 in the substrate plane 19 is determined by means of a pyrometer 40 from the not-to-be-processed side of the substrate 20, namely the side of the substrate 20 facing away from the means for processing 50, 60 and pointing towards the table 10, in particular to the first side 1001 of the table 10. In this example, it is the temperature of a substrate 20 positioned on a non-rotatable holder 11 that is measured and therefore of a substrate 20 that is only rotating with the rotation of the table 10 but not around a rotation axis of the holder 11 or around its own axis.

To create an optical path between the pyrometer 40 and the substrate 20, the table 10 comprises a first passage 21 for radiation to pass. This first passage 21 is arranged underneath the substrate 20 and thus within a region of the table 10 surrounded by the holder 11, or in other words, within a region of the table 10 defined or limited or bordered by the position of the holder 11. The first passage 21 in this example is not arranged centric but decentralized regarding the extension of the substrate 20 or the design/shape of the holder 11. However, it is also possible to have the first passage 21 designed in a centric manner for a static holder 11. To complete the optical path between the pyrometer 40 and the substrate 20, the holder 11 provides a second passage 22 for radiation to pass, e.g., by having an opening due to its general design as ring-shaped chuck or by being at least partially made from a material transparent to radiation. The location of the pyrometer 40 and the location of the first passage 21 of the table 10 and the second passage 22 of the holder 10 are coordinated such that they are at least partially brought into line within a 360° rotation of the table 10 once. The table 10, having, e.g., a diameter of 1300 mm, rotates with 40 rpm, for instance, wherein the holders 11 are located not at the circumference of the table 10 but rather along a circle with a diameter of, e.g., 1000 mm. The minimum diameter of the passages 21, 22 contributing to the optical path is 40 mm, for instance. The spot size of the pyrometer 40 is, e.g., 20 mm or less, such as 15 mm, and the pyrometer comprises a length of, e.g., 30 mm. The distance between the substrate plane 19 and the pyrometer 40 various, e.g., between 200 mm and 400 mm, the table 10 being in particular height-adjustable.

FIG. 2 shows a sectional view of a substrate processing apparatus 1 comprising a vacuum enclosure 2 accommodating a table 10 rotatable around a first rotation axis x. In case the table 10 has an essentially cylindric shape and is thus rotationally symmetric, the first rotation axis x may be identical in position to the rotational symmetry axis of the table 10. Compared to the substrate processing apparatus 1 shown in FIG. 1, the substrate processing apparatus 1 of FIG. 2 comprises two holders 11a,b instead of only one holder 11, Each holder 11a,b being constructed to support a substrate 20a,b in a substrate plane 19a,b. The holders 11a,b are arranged on the first side 1001 of the table 10, the set-up of the first holder 11a being identical to the one holder 11 shown in FIG. 1. The second holder 11b, however, is arranged rotatable around a second rotation axis y on the table 10. This second rotation axis y is, e.g., defined such that a rotational symmetric substrate 20b (e.g., having an essentially cylindric shape) positioned on the second holder 11b is rotated around its rotational symmetry axis when the holder 11b rotates around the second rotation axis y. The holders 11a,b are, for instance, designed as continuous or interrupted ring-shaped chucks, supporting the circumference of the substrates 20a,b. In order to process the substrates 20a,b, the substrate processing apparatus 1 comprises at least a heater 50 and/or a source 60 as already explained in connection with FIG. 1. To monitor the substrate processing, the temperature of at least one of the substrates 20a,b in the substrate processing apparatus 1 is determined by means of a pyrometer 40 from the second side of the table 1002 and thus from the not-to-be-processed side of the at least one of the substrates 20a,b. In this example, it is the temperature of the first substrate 20a positioned on the first holder 11a not rotating around a second rotation axis that is measured. The table 11 itself is nonetheless rotatable around axis x such that the first substrate 20a positioned on the first holder 11a is in movement. The first and the second substrate 20a,b are preferably identical regarding material, size and such. However, in one example, the first substrate 20a is a dummy substrate and the second substrate 20b is not. The dummy substrate is preferably a silicon Si dummy substrate. The dummy substrate is basically used as “monitoring” substrate. It can either be of a certain and different material (beneficially a cheaper material, such as glass) than the other non-dummy substrates, but also of the same material and quality. The dummy substrate can be used to monitor the coating thickness and the temperature, for instance. Depending on the method used for monitoring, the dummy substrate is damaged and will thus be disposed after analysis. Sometimes a dummy substrate for quality assurance is only used in every 10 or 15 cycle and not in each run of the apparatus. In general, the monitoring is more precise when the dummy substrate is positioned on the same holder always and in particular when said holder is a static, and thus non-rotating holder. To create an optical path between the pyrometer 40 and the first substrate 20a, a first passage 21 and a second passage 22 are provided as already explained in connection with the substrate processing apparatus 1 FIG. 1. Since the pyrometer 40 of the substrate processing apparatus 1 of the example of FIG. 2 is not hosted within the vacuum enclosure 2, the vacuum enclosure 2 comprises a third passage 23 to pass radiation, in particular radiation of a specific wavelength or specific wavelength range. The third passage 23 is made of germanium Ge or silicon Si, for instance. This third passage 23 provides for a continuation of the optical path between the pyrometer 40 and the substrate 20a and is arranged such that it is at least partially in line with the pyrometer 40 and the first passage 21 of the table 10 and the second passage 22 provided by the first holder 11a, whenever these three are at least partially brought in line by means of the rotational movement of the table 10.

FIG. 3 shows a sectional view of a substrate processing apparatus 1 comparable to the substrate processing apparatus of FIG. 2 with the difference that it is not only one pyrometer 40 that is used for measuring the temperature of the first substrate 20a. In this example, the substrate processing apparatus 1 comprises a pyrometer 40 and an additional pyrometer 41. The pyrometer 40 and the additional pyrometer 41 measure the temperature preferably in an alternating manner such that the temperature can be determined in a higher frequency than it is possible with only implementing one pyrometer since a pyrometer has a certain integration time being a delimiting factor here.

FIG. 4 shows a sectional view of a substrate processing apparatus 1 comparable to the substrate processing apparatus of FIG. 2 with the difference that it comprises in addition an optical monitor 30 for monitoring the processing of the substrates 20a,b from their to-be-processed side. Since the optical monitor 30 is arranged outside the vacuum enclosure 2, a fourth passage 24 to pass radiation is required to create an optical path between the optical monitor 30 and the substrates 20a,b. In this example, the fourth passage 24 is located opposite to the third passage 23 and the two are arranged on opposite sides of the substrates 20a,b and the substrate planes 19a,b, respectively. Both the pyrometer 40 and the optical monitor can be used to control, e.g., by means of a feedback loop, the source 60 and/or the heater 50. Please note that it is sufficient to implement one of the two for controlling the source 60 and/or the heater 50.

FIG. 5 shows a perspective view of a substrate processing apparatus 1 according to the invention. The rotatable table 10 in this example comprises in total four substrate holders 11, wherein three of the holders 11 support a substrate 20 each. On the fourth holder 11, there is no substrate positioned yet and the specific design of the holder 11 is visible. In the middle of the holder 11 the shaft 15 carrying the holder 11 and forming the rotation axis of the holder 11 is indicated. The holder 11 rotates in the same direction than the table 10. The holder 11 comprises two of the so-called second passages 22 comprising a halfmoon shape each. Since the shaft 15 is arranged centric, the second passages 22 are arranged decentralized and rather at the edges of the holder 11. The same applies for the first passage(s) of embodiments with holders that are ring-shaped or alike. The first passage of the table 10 is not indicated as it is superposed by the two second passages 22 and at least in parts by the holder 11 and is thus only visible through the second passages 22. In the rotation position shown, the light emitted of a substrate (see arrow pointing towards pyrometer 40) positioned on the holder 11 can pass through the second passage 22 on the right-hand side, the underlying first passage and the third passage 23 of the vacuum enclosure 2 of the substrate processing apparatus 1 to finally hit the pyrometer 40. To gain the most reliable results in temperature measurement, it is an approach to synchronize the emission measurement and rotation of the substrates 20 or the holders 11, respectively. The substrates 20 in this example are treated by a heater 50 and a source 60.

FIG. 6a shows a top view of embodiments of holders 11 to be used in a substrate processing apparatus according to the invention. The holder 11 on the left-hand side is supported by a centric shaft 15 and comprises two C-shaped and so-called second passages 22. The second passages 22 are mirror symmetrical (symmetry planes indicated by dotted and rectangular lines) and adapted to the basic round shape of the holder 11. The second passages 22 comprise the same segmental thickness (indicated by double arrows) throughout their whole extent. Furthermore, the outer circumferences of the second passages 22 are equidistant to the circumference of the holder 11 and their inner circumferences are equidistant to the centric shaft 15, both distances indicated by “double arrows” defined by rhombs.

The holder 11 shown in the middle comprises two mirror-symmetrical (symmetry planes indicated by dotted and rectangular lines) and C-shaped second passages 22. The second passages 22 comprise the same segmental thickness (indicated by double arrows) throughout their whole extent. However, the outer circumferences of the second passages 22 are not equidistant to the circumference of the holder 11 and their inner circumferences are not equidistant to the centric shaft 15. What is the case is that the outer circumferences of the C-shaped second passages 22 are closer to the circumference of the holder 11 at the endings of the C-shaped second passages 22 and further apart in their middle and that the inner circumferences are closer to the centric shaft 15 in the middle and further apart at the endings of the C-shaped second passages 22.

The holder 11 shown on the right-hand side comprises two mirror-symmetrical (symmetry planes indicated by dotted and rectangular lines) and C-shaped second passages 22. The shape of the second passages 22 can be further specified as halfmoon-shaped, wherein the outer circumference is adapted to the round circumference of the holder 11. This means that the distance of the outer circumferences of the second passages 22 are equidistant to the circumference of the holder 11. Since the halfmoon-shape is characterized by being thicker in the middle and becoming narrower and narrower the closer it comes to the tapering endings, the inner circumferences of the second passages 22 are closer to the centric shaft 15 in their middle.

FIG. 6b shows a top view and a cross section (underneath the top view) of one embodiment of a holder 11 to be used in a substrate processing apparatus according to the invention. The design of the holder 11 is comparable to the holder shown on the left-hand side in FIG. 6a. The cutting line runs through the shaft 15, which is constructed to rotationally drive the holder 11, and the middle segment of the C-shaped second passages 22.

FIG. 6c shows a top view of embodiments of holders 11 to be used in a substrate processing apparatus according to the invention. The two holders on the left-hand side are embodiments of the very left holder already described in connection with FIG. 6a. However, instead of the two C-shaped and so-called second passages, the holders 11 here show four or three C-shaped second passages 22. The holder 11 on the right-hand side comprises only a single second passage 22 which is round. All shown holders are supported by a centric shaft 15.

FIG. 7 shows a sectional view of a substrate processing apparatus 1 comprising a vacuum enclosure 2 accommodating a table 10 rotatable around a first rotation axis x. In case the table 10 has an essentially cylindric shape and is thus rotationally symmetric, the first rotation axis x may be identical in position to the rotational symmetry axis of the table 10. Furthermore, the substrate processing apparatus comprises two holders 11,11b for supporting a substrate 20,20b each, the holders 11,11b being arranged on the top side of the table 10, also called first side 1001. The holders 11,11b are arranged rotatable around a second rotation axis y and a third rotation axis y′ on the table 10. This second and third rotation axis y,y′ are, e.g., defined such that a rotational symmetric substrate 20,20b (e.g., having an essentially cylindric shape) positioned on the rotatable holder 11,11b or the rotational symmetric holder 11,11b itself is rotated around its rotational symmetry axis when the holder 11,11b rotates around the second or third rotation axis y,y′. The holders 11,11b are, for instance, designed as continuous or interrupted ring-shaped chucks, supporting the circumference of the substrates 20,20b. In order to process the substrates 20,20b, the substrate processing apparatus 1 comprises at least a heater 50 and/or a source 60 (e.g., CVD source or PVD source such as a target or sputter source). The heater 50 and the source 60 are both (if both are present, otherwise this statement applies to the one of them being present) arranged in the top region of the substrate processing apparatus 1 such that they can process the substrates 20 from the side not pointing to but facing away from the first side of the table 1001, when the substrates 20,20b pass by the heater 50 and/or source 60 driven by the rotatable table 10. To monitor the substrate processing, the temperature of at least one of the substrates 20 in the substrate processing apparatus 1 is determined by means of a pyrometer 40 from the second side of the table 1002 and thus from the non-processed side of the at least one of the substrates 20. To create an optical path between the pyrometer 40 and the at least one of the substrates 20, the table 10 comprises a first passage 21 for leading through radiation. This first passage 21 is arranged underneath the at least one of the substrates 20 and thus within a region of the table 10 surrounded by the holder 11, or in other words, a region of the table 10 defined by the position of the holder 11. The first passage 21 is preferably not arranged centric but decentralized regarding the second rotation axis y. The location of the pyrometer 40 and the location of the first passage 21 of the table 10 are coordinated such that they are at least partially brought into line within a 360° rotation of the table 10 once. In case the pyrometer 40 of the substrate processing apparatus 1 is not hosted within the vacuum enclosure 2, as it is the case in this example, the vacuum enclosure 2 comprises a third passage 23 for leading through radiation, in particular radiation of a specific wavelength or wavelength range. The third passage 23 is for instance made of germanium or silicon. This third passage 23 provides for a continuation of the optical path between the pyrometer 40 and the at least one of the substrates 20 and is arranged such that it is at least partially in line with the pyrometer 40 and the first passage 21 of the table 10 whenever these two are at least partially brought in line by means of the rotational movement of the table 10. The design of the holder 11 as continuous or interrupted ring-shaped chuck inherently provide for the second passage 22, completing the optical path between the pyrometer 40 and the at least one of the substrates 20. The spot size of the pyrometer 40, namely the radius of the beam of radiation it can receive, is 20 mm, for instance. In consequence, the minimum radius of the first passage 21, the second passage 22 and the third passage 23 should be minimum of the same diameter or larger. In particular the optical path they provide for should have at least the same or rather a larger diameter. Depending on the distance of the pyrometer 40 to the holder 11, it is also possible to install at least one or more lenses (not shown) within the optical path, in particular in front of the pyrometer 40, to achieve that the beam of radiation fits the size of the spot size of the pyrometer 40.

FIG. 8 shows a sectional view of a substrate processing apparatus 1 comparable to the one shown in FIG. 7. The substrate processing apparatus 1 comprises also a vacuum enclosure 2 housing a table 10 rotatable around a first rotation axis x. Furthermore, two holders 11, both rotatable around a second rotation axis y, are arranged on the table 10 supporting a substrate 20 each. For instance, the rotational drive can be provided by a shaft in the center of the holder but also by a gear drive or a belt drive driving the holder 11 not centric but circumferential. A heater 50 and/or a source 60 are provided in the top region for processing the substrates 20 pointing towards the first side of the table 1001. A pyrometer 40 is installed outside of the vacuum enclosure 2 for measuring the temperature of a substrate 20 from the side of the substrate 20 pointing towards the first side of the table 1001. Radiation from the inside of the vacuum enclosure 2 can pass through the third passage 23 of the vacuum enclosure 2 to get detected by the pyrometer 40. The table 10 comprises first passage 21 that can be synchronized with the pyrometer 40 and the third passage 23. Opposite to the example shown in FIG. 7, the holders 11 are not designed ring-shaped but solid. In consequence, it is not only the table 10 but also the holder 11 that needs a passage, the so-called second passage 22 for the creation of an optical path between the substrate 20 and the pyrometer 40. This second passage 22 is also to be synchronized with the first passage 21 of the table 10, the third passage 23 of the enclosure 2 and the pyrometer 40. In addition, the substrate processing apparatus 1 of this example comprises an optical monitor 30 for further monitoring the processing of the substrate from the top, namely from the side where the heater/source 50,60 are located. Since the optical monitor 30 is arranged outside the vacuum enclosure 2, a fourth passage 24 is required.

FIG. 9 shows a substrate processing apparatus 1 comprising a rotatable table 10 (rotatability is indicated by the arrow on the left-hand side drawn in dashed lines). The rotatable table 10 of this example is equipped with in total four holders 11, each holder 11 supporting a substrate 20. Furthermore, the processing apparatus 1 comprises a heater 50 for heating the substrates 20 from the top, namely from the side of the substrates 20 also pointing to the source 60 (e.g., CVD source or PVD source such as a target) arranged next to the heater, e.g., in line with the heater when viewed in rotation direction of the table 10. This means that the substrates 20 are heated and further processed (e.g., coated) from the same side. There is no heating from, and thus no heater arranged at, the side of the substrates 20 pointing away from the source 60. The heater 50 is arranged prior to the source 60 when viewed in direction of the rotation such that the substrates 20 rotated by means of the rotating table 10 are first heated and then further processed by means of the source 60. However, the substrates 20 may undergo various rotation cycles such that heating and further processing are executed several times in a row, normally starting with heating and finishing with further processing. In one example of the substrate processing apparatus 1 it is possible that the substrates 20 are not only rotated by means of the table 10 but also by means of the holders 11 and thus around their own axis. Apart from the already mentioned features, the enclosure 2 of the substrate processing apparatus 1 comprises a third passage 23 and a fourth passage 24. The third passage 23 and the fourth passage 24 are arranged opposite to each other such that they can view the same region 26 of a substrate 20 rotating therebetween, but through the third passage 23 this region 26 can be viewed from the bottom, namely the side of the facing away from the heater 50 and the source 60, and through the fourth passage 24 this region 26 can be viewed from the side pointing towards the heater 50 and the source 60. The straight arrows drawn in dashed lines help to visualize the optical path leading the radiation coming from the substrate 20 to the third and the fourth passage 23, 24 and thus to the first and the second pyrometer 40, 41 being optically connected to the third and the fourth passage 23,24, respectively. In the shown embodiment, the first and second pyrometer 40,41 are congruent. However, the pyrometers 40, 41 can also be arranged in an angular offset. Then, the pyrometers 40, 41 can, e.g., measure at the same time (triggered in the same manner, for instance) but different locations of the substrate or, as an alternative, measure at different times (e.g., software provides a trigger delay for one of the pyrometers 40,41) but the same location. In particular for larger substrates (e.g., larger than 200 mm diameter, such as 300 mm) or substrates of a different shape as round, such as rectangular, a temperature distribution is interesting to have (e.g., what is the temperature like in the center and what at the edge?). Please note that the first pyrometer 40 and additional pyrometer(s) 41 must not necessarily be arranged opposite but can also be arranged in some distance on the same side of the substrate processing apparatus 1, either sharing the same optical path (see, e.g., FIG. 3) or not. Apart from the size, the structure of the substrate can make a temperature determination at various locations of the substrate more interesting. Structured wafers are beneficially not heated above 180° C. (otherwise the semiconductor is damaged), for instance. A temperature distribution more reliably assures that the structured wafer is intact. In order to allow radiation from the substrates bottom side to reach the third passage 23 and thus the first pyrometer 40, the table 10 and the holder 11 (in case the holder is not ring-shaped or alike anyway) comprise both either a physical opening or a window transparent to radiation of a certain wavelength or wavelength range (e.g., IR radiation) forming a first and a second passage. These first and second passages are not visible in FIG. 9 as they are covered in the shown view by the substrates 20. To not measure the temperature of the bottom side of the table 10 instead of the temperature of the substrates 20, the pyrometers' measurement and the movement of the substrates can be synchronized, in particular the pyrometers' measurement and the movement of first and second passages of the table 10 and the holders 11 supporting the substrates 20. To achieve such a synchronization, the first pyrometer 40 is operationally connected to a trigger 45. The trigger 45 can be designed as a detector of a light barrier and is stimulated by a means for stimulation 46, such as a through whole in table and a source of light, such as a laser, mounted above said through hole (source of light not shown). As an alternative, the pyrometer 40 can be activated software-based. An encoder sends a signal whenever the holder 11 and/or table 10 passes a certain angle, a decoder processes said signal and triggers the pyrometer 40. In consequence, there is no physical trigger 45 but the activation of the pyrometer 40 is based on the position of the holder 11 and/or table 10, or rather the drive of the holder 11 and or the table 10, and software.

FIG. 10 shows a perspective view of a substrate processing apparatus 1 according to the invention. The table 10, which is in this case better considered as conveyer belt, shows in total three substrate holders 11, wherein two of the holders 11 support a substrate 20 each. The conveyer belt 10 moves in linear direction x and comprises in total far more than only three holders 11, however, only a section of the conveyer belt 10 is shown. On the third holder 11, there is no substrate positioned yet and the specific design of the holder 11 is visible. In the middle of the holder 11 the shaft 15 carrying the holder 11 and forming the rotation axis of the holder 11 is indicated. The holder 11 comprises only one second passage 22 having a round shape. Since the shaft 15 is arranged centric, the second passage 22 is arranged decentralized and rather at the edge of the holder 11. The first passage of the conveyer belt 10 is not indicated as it is superposed by the second passage 22 and at least in parts by the holder 11 and is thus only visible through the second passage 22. In the position shown, the light emitted of a substrate (see arrow pointing towards pyrometer 40) positioned on the holder 11 can pass through the second passage 22 and the underlying first passage to finally hit the pyrometer 40. The substrates 20 in this example are treated by a heater 50 and a source 60.

Reference Signs

| | |
|---|---|
| 1 | Substrate processing apparatus |
| 2 | Vacuum enclosure |
| 10 | Table |
| 1001 | First side of the table |
| 1002 | Second side of the table |
| 11 | Holder |
| 11a | First holder |
| 11b | Second holder |
| 15 | Shaft |
| 19 | Substrate plane |
| 19a | First substrate plane |
| 19b | Second substrate plane |
| 20 | Substrate |
| 20a | First substrate |
| 20b | Second substrate |
| 21 | First passage |
| 22 | Second passage |
| 23 | Third passage |
| 24 | Fourth passage |
| 25 | Fifth passage |
| 26 | Region substrate |
| 30 | Optical monitor |
| 40 | Pyrometer/First pyrometer |
| 41 | Additional pyrometer/Second pyrometer |
| 46 | Means for stimulation |
| 50 | Heater |
| 60 | Source |
| x | First axis |
| y | Second axis |

What is claimed is:

1. Substrate processing apparatus (1), comprising:
a table (10) rotatable around a first axis (x) and comprising at least one first passage (21) being transparent to radiation;
at least one first holder (11, 11a) for supporting a substrate (20, 20a) and defining a first substrate plane (19, 19a), the first holder (11, 11a) being arranged in a non-rotatable manner on a first side of the table (1001) and providing at least a second passage (22) being transparent to radiation;
at least one means (50; 60) for processing a substrate in the first substrate plane (19, 19a), the at least one means (50; 60) for processing a substrate being arranged facing the first substrate plane (19, 19a) and the first side of the table (1001); and
a pyrometer (40) being arranged on a second side of the table (1002), the second side of the table (1002) facing away from the first side of the table (1001);
wherein there is at least one position in a 360° rotation of the table (10) around the first axis (x) in which position the at least one first passage (21) and the at least one second passage (22) form an optically operative connection between the pyrometer (40) and the side of a substrate (20, 20a), when positioned in the first substrate plane (19, 19a), facing away from the at least one means (50; 60) for processing a substrate.

2. Substrate processing apparatus (1) according to claim 1, further comprising:
at least one second holder (11b) for supporting a substrate (20b) and defining a second substrate plane (19b), the second holder (11b) being arranged in a rotatable manner around a second axis (y) on said first side of the table (1001), the second axis (y) being different from the first axis (x);
wherein in particular no optically operative connection is provided between the pyrometer (40) and the side of a substrate (20b), when positioned in the second substrate plane (19b), facing away from the at least one means (50; 60) for processing a substrate, irrespective of the position of the table (10) in respect to the first axis (x) and/or irrespective of the position of the second holder (11b) in respect to the second axis (y).

3. Substrate processing apparatus (1), comprising:
a table (10) rotatable around a first axis (x) and comprising at least one first passage (21) being transparent to radiation;
at least one first holder (11) for supporting a substrate (20) and defining a first substrate plane (19), the first holder (11) being arranged in a rotatable manner around a second axis (y) on a first side of the table (1001) and providing at least a second passage (22) being transparent to radiation, the second axis (y) being in particular different from the first axis (x);
at least one means (50; 60) for processing a substrate in the first substrate plane (19), the at least one means (50; 60) for processing a substrate being arranged facing the first substrate plane (19) and the first side of the table (1001); and
a pyrometer (40) being arranged on a second side of the table (1002), the second side of the table (1002) facing away from the first side of the table (1001);
wherein there is at least one position in a 360° rotation of the table (10) around the first axis (x) and in a 360° rotation of the first holder (11) around the second axis (y) in which position the at least one first passage (21) and the at least one second passage (22) form an optically operative connection between the pyrometer (40) and the side of a substrate (20), when positioned in the first substrate plane (19), facing away from the at least one means (50; 60) for processing a substrate.

4. Substrate processing apparatus (1) according to claim 3, further comprising:
at least one second holder (11b) for supporting a substrate (20b) and defining a second substrate plane (19b), the second holder (11b) being arranged either in a rotatable manner around a third axis (y′) on said first side of the table (1001), the third axis (y′) being different from the first axis (x) and the second axis (y), or in a non-rotatable manner;
wherein in particular no optically operative connection is provided between the pyrometer (40) and the side of a substrate (20b), when positioned in the second substrate plane (19b), facing away from the at least one means (50; 60) for processing a substrate, irrespective of the position of the table (10) in respect to the first axis (x) and/or irrespective of the position of the second holder (11b) in respect to the third axis (y′).

5. Substrate processing apparatus (1) according to claim 1, wherein:
the table (10), the at least one means (50; 60) for processing a substrate in the first substrate plane and the at least one first holder (11,11a) or the at least one first holder (11,11a) and the at least one second holder (11b), respectively, are arranged within a vacuum enclosure (2); and
the pyrometer (40) is arranged outside of said vacuum enclosure (2),
the vacuum enclosure (2) comprising a third passage (23) being transparent to radiation, said third passage (23) forming together with the at least one first passage (21) and the at least one second passage (22) the optically operative connection between the pyrometer (40) and the side of a substrate (20), when positioned in the first substrate plane (19,19a), facing away from the at least one means (50; 60) for processing a substrate.

6. Substrate processing apparatus according to claim 1, wherein at least one of the first passage (21), the second passage (22) and the third passage (23) comprises silicon (Si) and/or germanium (Ge), preferably at least the third passage (23) comprises silicon (Si) and/or germanium (Ge).

7. Substrate processing apparatus according to claim 1, further comprising:
an additional pyrometer (41) being also in at least one position in a 360° rotation of the table (10) around the first axis (x) or in at least one position in a 360° rotation of the table (10) around the first axis (x) and in a 360° rotation of the first holder (11) around the second axis (y) in optically operative connection with the side of a substrate (20a), when positioned in the first substrate plane (19a), facing away from the at least one means (50; 60) for processing a substrate, by means of the at least one first passage (21) and the at least one second passage (22) or by means of the at least one first passage (21), the at least one second passage (22) and the at least one third passage (23) or by means of one or more passages being different from the at least one first passage (21), the at least one second passage (22) or from the at least one first passage (21), the at least one second passage (22) and the at least one third passage (23),
wherein the pyrometer (40) and the additional pyrometer (41) are configured to receive radiation from the side of a substrate (20a), when positioned in the first substrate plane (19a), facing away from the at least one means (50; 60) for processing a substrate, in particular configured to receive radiation in an alternating manner.

8. Substrate processing apparatus according to claim 1, further comprising:
an additional pyrometer (41) being in at least one position in a 360° rotation of the table (10) around the first axis (x) or in at least one position in a 360° rotation of the table (10) around the first axis (x) and in a 360° rotation of the first holder (11) around the second axis (y) in optically operative connection with the side of a substrate (20), when positioned in the first substrate plane (19), facing to the at least one means (50; 60) for processing a substrate, in particular by means of a fourth passage (24) being different from the at least one first passage (21), the at least one second passage (22), and the at least one third passage (23),
wherein the additional pyrometer (41) is configured to receive radiation from the side of a substrate (20), when positioned in the substrate plane (19), facing to the at least one means (50; 60) for processing a substrate.

9. Substrate processing apparatus according to claim 8, wherein:
the pyrometer (40) and the additional pyrometer (41) are arranged such that the optically operative connection with the side of a substrate (20), when positioned in the first substrate plane (19), facing away from the at least one means (50; 60) for processing a substrate, and the optically operative connection with the side of a substrate (20), when positioned in the first substrate plane (19), facing to the at least one means (50; 60) for processing a substrate, are congruent or distinct.

10. Substrate processing apparatus according to claim 1, wherein:
the pyrometer (40) and/or the additional pyrometer (41) are configured to receive radiation of a wavelength of 5 to 14 μm, in particular of 5 to 8 μm or 8 to 14 μm, further in particular of 7.9 μm or 12 μm.

11. Substrate processing apparatus according to claim 1, wherein:
the integration time of the pyrometer (40) and/or of the additional pyrometer (41) is 15 ms or less, in particular 10 ms or less, and further in particular 5 ms or less.

12. Substrate processing apparatus according to claim 1, wherein:
the optically operative connection between the side of a substrate (20,20a), when positioned in the first substrate plane (19,19a), facing away from the at least one means (50; 60) for processing a substrate, and the pyrometer (40) and/or the additional pyrometer (41) is designed such that the pyrometer (40) and/or the additional pyrometer (41) receive radiation emitted centralized from the substrate (20,20a) and/or decentralized from the substrate (20,20a).

13. Substrate processing apparatus according to claim 1, further comprising an optical monitor (30) and/or at least one lens being part of the optically operative connection between the pyrometer (40) and the substrate (20, 20a), in particular by forming the third passage (23), and/or at least one lens being part of the optically operative connection between the additional pyrometer (41) and the substrate (20, 20a), in particular by forming the third passage (23) or the fourth passage (24).

14. Substrate processing apparatus according to claim 1, further comprising at least one means for synchronization to synchronize the emission measurement performed by the pyrometer (40) and/or by the additional pyrometer (41) and the rotation of the table (10) around the axis (x) and/or the rotation of the first holder (11) around the second axis (y), such that the pyrometer (40) and/or the additional pyrometer (41) measure emission only when they are in optically operative connection to the substrate, when positioned in the first substrate plane.

15. Substrate processing apparatus according to claim 1, further comprising at least one means for synchronization to synchronize the forwarding of the emission measurement performed by the pyrometer (40) and/or by the additional pyrometer (41) and the rotation of the table (10) around the axis (x) and/or the rotation of the first holder (11) around the second axis (y), such that only emission measurements performed when the pyrometer (40) and/or the additional pyrometer (41) are in optically operative connection to the substrate, when positioned in the first substrate plane, are forwarded,
wherein the synchronization mechanism of the means for synchronization is in particular based on the rise of the signal caused by the establishment of the optically operative connection between the pyrometer (40) and/or the additional pyrometer (41) and the substrate, when positioned in the first substrate plane, and further in particular based on the fall of the signal caused by the termination of the optically operative connection between the pyrometer (40) and/or the additional pyrometer (41) and the substrate, when positioned in the first substrate plane.

16. Substrate processing apparatus according to claim 1, wherein the pyrometer (40) and/or the additional pyrometer (41) are configured to measure a temperature permanently during a 360° rotation of the table (10) around the first axis (x), and
wherein the pyrometer (40) and/or the additional pyrometer (41) are configured to only forward maximum values, in particular 1 to 3 maximum values per one 360° rotation, or wherein the substrate processing apparatus further comprises a controlling device in operational connection with the pyrometer (40) and/or the additional pyrometer (41) and configured to identify and forward maximum values only, in particular 1 to 3 maximum values per one 360° rotation.

17. Substrate processing apparatus according to claim 1, wherein the table (10) is configured to have a speed between 12 to 120 rpm, in particular approximately 40 rpm.

18. Use of a substrate processing apparatus according to claim 1 for measuring the temperature of a substrate (20, 20a), in particular of a moving substrate (20,20a) and further in particular of a rotating substrate (20,20a), the rotating substrate (20,20a) preferably rotating around a first rotation axis (x) and/or a second rotation axis (y).

19. Method of measuring the temperature of a moving substrate (20,20a), the method comprising:
rotating a substrate (20,20a) around a first axis (x) on a table (10) of a substrate processing apparatus (1), in particular with a speed of 12 to 120 rpm and further in particular of 40 rpm;
providing at least one means (50; 60) for processing the substrate (20,20a) from a first side;
receiving radiation emitted from a second side of the substrate (20,20a) by means of a pyrometer (40) through an optically operative connection between the pyrometer (40) and the substrate (20, 20a), the second side being opposite to said first side.

20. Method according to claim 19, further comprising:
rotating the substrate (20) around a second axis (y) on a holder (11) supporting said substrate (20) and arranged on the table (10).

21. Method according to claim 19, further comprising at least one of the following:
receiving radiation emitted from the second side of the substrate (20,20a) by means of an additional pyrometer (41) through the optically operative connection between the pyrometer (40) and the substrate (20, 20a), the second side being opposite to said first side;
receiving radiation emitted from the second side of the substrate (20,20a) by means of an additional pyrometer (41) through an additional optically operative connection between the additional pyrometer (41) and the substrate (20, 20a), the second side being opposite to said first side;
receiving radiation emitted from the first side of the substrate (20,20a) by means of an additional pyrometer (41) through an additional optically operative connection between the additional pyrometer (41) and the substrate (20,20a).

22. Method according to claim 19, further comprising:
synchronizing the rotation of the substrate (20) around the first axis (x) and/or the second axis (y) with at least one of the following:
the reception of radiation through the optically operative connection between the pyrometer (40) and the substrate (20,20a);
the reception of radiation through the optically additional operative connection between the additional pyrometer (41) and the substrate (20,20a).

23. Method according to claim 21, wherein:
the reception of radiation emitted from a second side of the substrate (20,20a) by means of a pyrometer (40) through an optically operative connection between the pyrometer (40) and the substrate (20, 20a), the second side being opposite to said first side, and
the reception of radiation emitted from the first side of the substrate (20,20a) by means of an additional pyrometer (41) through an additional optically operative connection between the additional pyrometer (41) and the substrate (20,20a) are at least one of the following:
performed at the same time;
performed temporally shifted;
performed congruent;
performed distinct.

24. Method according to claim 19, wherein the pyrometer (40) and/or the additional pyrometer (41) receives radiation only or processes the received radiation to a temperature value only, when the pyrometer (40) and/or the additional pyrometer (41) is in optically operative connection with the substrate (20, 20a).

25. Method according to claim 19, further comprising:
receiving radiation emitted from the table (10) by means of the pyrometer (40) and/or the additional pyrometer (41),
wherein only emission measurements performed when the pyrometer (40) and/or the additional pyrometer (41) is in optically operative connection with the substrate (20, 20a) are provided, in particular by a means of synchronization, by a controlling device or by the pyrometer (40) and/or the additional pyrometer (41) itself; or
wherein only emission measurements performed when the pyrometer (40) and/or the additional pyrometer (41) is in optically operative connection with the table (10) and not with the substrate (20, 20a) are provided; or
wherein emission measurements performed when the pyrometer (40) and/or the additional pyrometer (41) is in optically operative connection with the table (10) and with the substrate (20, 20a) are provided.
